(19) United States
(12) Patent Application Publication
(10) Pub. No.: US 2023/0335648 A1
(43) Pub. Date: Oct. 19, 2023

(54) THIN FILM TRANSISTOR AND MANUFACTURING METHOD FOR THIN FILM TRANSISTOR

(71) Applicant: ADRC. CO. KR, Seoul (KR)

(72) Inventors: Jin JANG, Seoul (KR); Hae Su HONG, Seoul (KR)

(21) Appl. No.: 18/108,084

(22) Filed: Feb. 10, 2023

(30) Foreign Application Priority Data
Apr. 18, 2022 (KR) 10-2022-0047537

(51) Int. Cl. H01L 29/49; H01L 29/786; H01L 21/02; H01L 29/66

(52) U.S. Cl. CPC H01L 29/78693; H01L 21/02565; H01L 21/02592; H01L 21/02628; H01L 29/4908; H01L 29/66969

(57) ABSTRACT

A thin film transistor manufacturing method according to an embodiment includes: forming a gate electrode on a substrate; forming a gate insulation layer on the gate electrode; forming a semiconductor layer on the gate insulation layer; and forming a source electrode and a drain electrode that contact the semiconductor layer, wherein the forming of the gate insulation layer and the forming of the semiconductor layer include spray coating on the substrate.

### CROSS-REFERENCE TO RELATED APPLICATION

This application claims priority to and the benefit of Korean Patent Application No. 10-2022-0047537 filed in the Korean Intellectual Property Office on Apr. 18, 2022, the entire contents of which are incorporated herein by reference.

### BACKGROUND

### 1. Field

The present disclosure relates to a thin film transistor and a manufacturing method of the thin film transistor.

### 2. Description of the Related Art

A thin film transistor forms a switching element with three terminals of a gate electrode to which a control signal is applied, a source electrode to which a data voltage is applied, and a drain electrode to output the data voltage. In addition, this thin film transistor includes an active layer overlapping the gate electrode as a channel layer, and the active layer includes a semiconductor.

Meanwhile, with the development of a display technology including a thin film transistor, the development of a thin film transistor capable of high-speed driving is urgently needed. For this purpose, a technology using an oxide semiconductor with high electron mobility as an active layer has been developed, but a thin film transistor with improved performance is required to be used for high-speed operation.

In addition, since a manufacturing process of a thin film transistor with improved performance increases as the manufacturing process becomes more complicated, it is necessary to provide a thin film transistor manufacturing method that can simplify the manufacturing process to lower the manufacturing cost while maintaining high performance.

The above information disclosed in this Background section is only for enhancement of understanding of the background of the described technology, and therefore it may contain information that does not form the prior art that is already known in this country to a person of ordinary skill in the art.

### SUMMARY

Embodiments are to provide a thin film transistor that can maintain high performance while reducing manufacturing cost, and a thin film transistor manufacturing method.

However, the problems to be solved by the embodiments are not limited to the above-described problems and may be variously expanded in the range of the technical ideas included in the embodiments.

A thin film transistor according to an embodiment includes: a gate electrode disposed on a substrate; a semiconductor layer that overlaps the gate electrode, while disposing the gate insulation layer therebetween; and a source electrode and a drain electrode that contact the semiconductor layer, wherein the semiconductor layer includes an amorphous oxide semiconductor, the amorphous oxide semiconductor is formed by spray coating, and an average surface roughness difference of an atomic force microscope (AFM) of the amorphous oxide semiconductor is about 1 nm and less.

The gate insulation layer may contain a zinc aluminum oxide (ZAO).

The semiconductor layer may contain indium.

The semiconductor layer may contain at least one of an indium-gallium-zinc oxide (IGZO), an indium-zinc-tin oxide (IZTO), an indium-gallium-zinc-tin oxide (IGZTO), and an indium-gallium oxide (IGO).

The thin film transistor may further include a first gate electrode that overlaps the semiconductor layer, wherein the first gate electrode may be applied with the same voltage applied to the gate electrode.

The gate insulation layer may include a first gate insulation layer and a second gate insulation layer disposed on the first gate insulation layer.

The first gate insulation layer may contain any one of aluminum oxide (Al₂O₃), a zinc aluminum oxide (ZAO), and a zirconium oxide (ZrO₂), and the second gate insulation layer may contain any one of a zinc aluminum oxide (ZAO) and silicon dioxide (SiO₂).

The semiconductor layer may include a first semiconductor layer and a second semiconductor layer disposed on the first semiconductor layer.

The first semiconductor layer may include any one of an indium-gallium-zinc oxide (IGZO) and an indium-gallium-zinc-tin oxide (IGZTO), and the second semiconductor layer may include any one of an indium-gallium oxide (IGO) and an indium-zinc oxide (IZTO).

A thin film transistor manufacturing method according to an embodiment includes: forming a gate electrode on a substrate; forming a gate insulation layer on the gate electrode; forming a semiconductor layer on the gate insulation layer; and forming a source electrode and a drain electrode that contact the semiconductor layer, wherein the forming of the gate insulation layer and the forming of the semiconductor layer include spray coating on the substrate.

The forming of the gate insulation layer may include: preparing a first process solution in a spray coating device; spraying the first process solution to the substrate together with a carrier gas; and evaporating a volatile solvent contained in the first process solution.

The forming of the semiconductor layer may include: preparing a second process solution in the spray coating device; spraying the second process solution to the substrate together with the carrier gas; and evaporating a volatile solvent contained in the second process solution.

The forming of the semiconductor layer may be carried out under a process temperature of about 320° C. to about 380° C.

The forming of the semiconductor layer may be carried out under a process temperature of about 325° C. to about 375° C.

The gate insulation layer may contain a zinc aluminum oxide (ZAO), and the first process solution may contain a precursor of the zinc aluminum oxide.

The semiconductor layer may further include an amorphous oxide semiconductor, and the second process solution may include a precursor of the oxide semiconductor.

According to the thin film transistor and the thin film transistor manufacturing method according to the embodiment, it is possible to lower the manufacturing cost and maintain high performance.

However, the effects of the embodiments are not limited to the above-described effects, and it is evident that this disclosure can be variously extended in a range that does not deviate from the spirit and region of this disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a perspective view of a thin film transistor according to an embodiment.

FIGS. 2 to FIG. 4 are perspective views of a manufacturing method of a thin film transistor according to according to an embodiment.

FIG. 5 is a cross-sectional view of a thin film transistor according to another embodiment.

FIG. 6 is a cross-sectional view of a thin film transistor according to another embodiment.

FIGS. 7 to FIG. 10 are electron microscope photos of a result of an experimental example.

FIG. 11 is a graph illustrating a result of the experimental example.

FIGS. 12 to FIG. 14 are graphs illustrating a result of another experimental example.

FIG. 15 is a graph showing results of another experimental example.

FIG. 16 to FIG. 17 are graphs illustrating results of another experimental example.

FIG. 18 and FIG. 19 are graphs illustrating results of another experimental example.

FIGS. 20 to FIG. 28 are graphs illustrating results of another experimental example.

### DETAILED DESCRIPTION

Hereinafter, with reference to the accompanying drawings, various embodiments will be described in detail such that a person of ordinary skill in the technical field to which this disclosure belongs can easily practice it. This disclosure may be implemented in several different forms and is not limited to the embodiments described herein.

In order to clearly explain this disclosure, parts irrelevant to the description are omitted, and the same reference sign is attached to the same or similar constituent elements throughout the specification.

In addition, the attached drawings are only for easy understanding of the embodiment disclosed in the present specification, and the technical ideas disclosed in this specification are not limited by the attached drawings, and all changes included in the spirit and technical range of this disclosure should be understood to include equivalents or substitutes.

In addition, since the size and thickness of each component shown in the drawing are arbitrarily indicated for convenience of explanation, this disclosure is not necessarily limited thereto. In the drawings, the thickness of layers, films, panels, regions, etc., are exaggerated for clarity. Further, in the drawing, for convenience of explanation, the thickness of some layers and regions is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be disposed above or below the target element, and will not necessarily be understood to be disposed “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, throughout the specification, when “connected to” in the entire specification, this does not only mean that two or more constituent elements are directly connected, but also means that two or more constituent elements are indirectly connected, physically connected, and electrically connected through other constituent elements, or being referred to by different names depending on the position or function, while being integral.

Hereinafter, various embodiments and exemplary variations will be described with reference to the accompanying drawings.

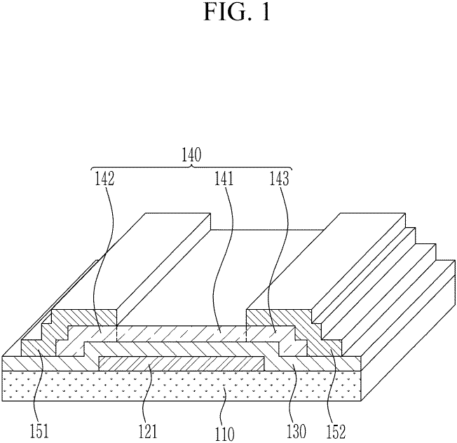

Referring to FIG. 1, a thin film transistor according to an embodiment will be described. FIG. 1 is a perspective view of a thin film transistor according to an embodiment.

Referring to FIG. 1, a gate electrode 121 may be disposed on a substrate 110, and a gate insulation layer 130 may be disposed on the gate electrode 121.

The gate electrode 121 may be a single layer including any one of copper (Cu), a copper alloy, aluminum (Al), an aluminum alloy, molybdenum (Mo), and a molybdenum alloy, or a plurality of layers in which metal layers are stacked.

The gate insulation layer 130 may include one of a zinc aluminum oxide (ZAO), aluminum oxide (Al₂O₃), silicon dioxide (SiO₂), and zirconium oxide (ZrO₂), and the gate insulation layer 130 may be formed by a spray coating method.

A semiconductor layer 140 including a first region 141, a second region 142, and a third region 143 is disposed on the gate insulation layer 130.

The semiconductor layer 140 may include an amorphous oxide semiconductor (AOS). The oxide semiconductor may include at least one of a primary metal oxide such as an indium (In) oxide, a tin (Sn) oxide (Sn), or a zinc (Zn) oxide, a binary metal oxide such as an In-Zn-based oxide, a Sn-Zn-based oxide, an Al-Zn-based oxide, a Zn-Mg-based oxide, a Sn-Mg-based oxide, an In-Mg-based oxide, or an In-Ga-based oxide, a ternary metal such as an In-Ga-Zn-based oxide, an In-Al-Zn-based oxide, an In-Sn-Zn-based oxide, a Sn-Ga-Zn-based oxide, an Al-Ga-Zn-based oxide, a Sn-Al-Zn-based oxide, an In-Hf-Zn-based oxide, an In-La-Zn-based oxide, an In-Ce-Zn-based oxide, an In-Pr-Zn-based oxide, an In-Nd-Zn-based oxide, an In-Sm-Zn-based oxide, an In-Eu-Zn-based oxide, an In-Gd-Zn-based oxide, an In-Tb-Zn-based oxide, an In-Dy-Zn-based oxide, an In-Ho-Zn-based oxide, an In-Er-Zn-based oxide, an In-Tm-Zn-based oxide, an In-Yb-Zn-based oxide, or an In-Lu-Zn-based oxide, and a quaternary metal oxide such as an In-Sn-Ga-Zn-based oxide, an In-Hf-Ga-Zn-based oxide, an In-Al-Ga-Zn-based oxide, an In-Sn-Al-Zn-based oxide, an In-Sn-Hf-Zn-based oxide, or an In-Hf-Al-Zn-based oxide.

The semiconductor layer 140 may include at least one of an indium-gallium-zinc oxide (IGZO), an indium-zinc-tin oxide (IZTO), an indium-gallium-zinc-tin oxide (IGZTO), and an indium-gallium oxide (IGO).

The semiconductor layer 140 may be formed by a spray method, and the spray solution may include a stabilizer, and the stabilizer may include ammonium acetate (CH₃CO₂NH₄) (AA).

A difference in the average height of the surface roughness of the surface of the semiconductor layer 140 measured with an atomic force microscope (AFM) may be about 1 nm or less, and more specifically, about 0.86 nm or less.

The first region 141 of the semiconductor layer 140 may be a channel region, and the second region 142 and the third region 143 of the semiconductor layer 140 may be a source region and a drain region, respectively.

A source electrode 151 is disposed on the second region 142 that is the source region of the semiconductor layer 140, and a drain electrode 152 is disposed on the third region 143 that is the drain region of the semiconductor layer 140.

The source electrode 151 and the drain electrode 152 may include an aluminum-based metal, a silver-based metal, and a copper-based metal having low resistivity, and may have a triple-layered structure of a lower layer containing a refractory metal such as titanium, molybdenum, chromium, and tantalum or alloys thereof, a middle layer containing an aluminum-based metal, a silver-based metal, and a copper-based metal having low resistivity, and an upper layer containing a refractory metal such as titanium, molybdenum, chromium, and tantalum.

The gate electrode 121, the source electrode 151, and the drain electrode 152 described above form a thin film transistor together with the semiconductor layer 140, and a channel of the thin film transistor is formed between the second region 142, which is the source region of the semiconductors 141, 142, and 143, and the third region, which is the drain region.

In the thin film transistor according to the present embodiment, the gate insulation layer 130 and the semiconductor layer 140 may be formed by spray coating, and the semiconductor layer 140 may include an amorphous oxide semiconductor.

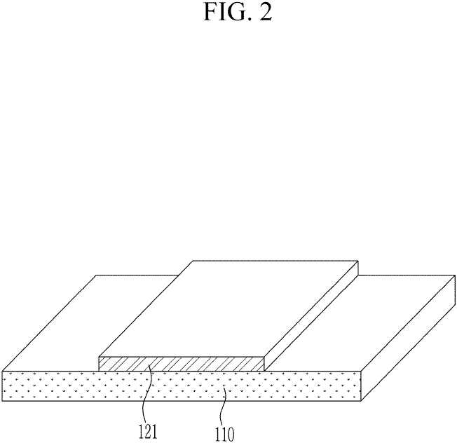

Hereinafter, a manufacturing method of the thin film transistor according to an embodiment will be described with reference to FIG. 2 to FIG. 4, together with FIG. 1. FIG. 2 to FIG. 4 are perspective views of a manufacturing method of a thin film transistor according to according to an embodiment.

Referring to FIG. 2, a gate electrode 121 is formed on the substrate 110.

A metal layer forming the gate electrode 121 on the substrate 110, for example, a single layer including any one of copper (Cu), a copper alloy, aluminum (Al), an aluminum alloy, molybdenum (Mo), and a molybdenum alloy or a plurality of layers in which a metal layer including the same is stacked on the substrate 110, a photosensitive layer pattern is formed on the plurality of layers, and the photosensitive layer pattern is etched using an etching mask such that the gate electrode 121 may be formed.

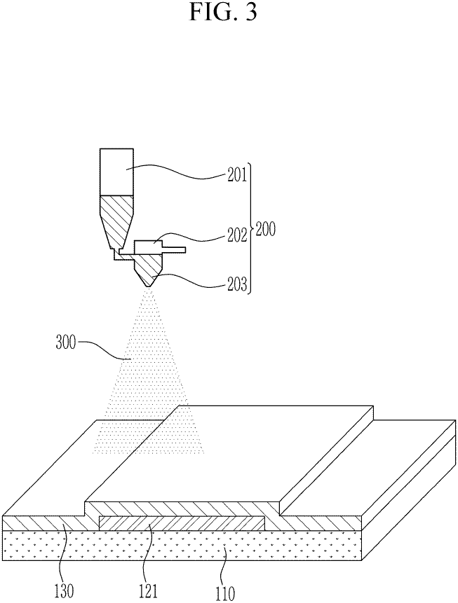

Referring to FIG. 3, the gate insulation layer 130 may be formed on the substrate 110 including the gate electrode 121 by a spray coating method using a spray coating device 200.

The spray coating device 200 may include a solution supply portion 201 accommodating a spray solution, a gas supply portion 202, and a nozzle 203.

A process for forming the gate insulation layer 130 may include: preparing a first process solution by mixing a precursor of zinc aluminum oxide (ZAO) in a volatile solvent; spraying the first process solution on the substrate 110 through the nozzle 203 together with a carrier gas such as nitrogen supplied through the gas supply portion 202; and evaporating the volatile solvent contained in the first process solution.

Forming the gate insulation layer 130 may be performed under a process temperature of about 320° C. to about 380° C., more specifically about 325° C. to about 375° C.

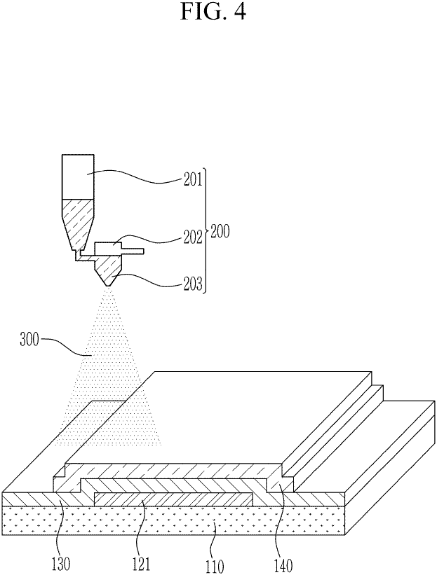

Referring to FIG. 4, the semiconductor layer 140 may be formed by a spray coating method using a spray coating device 200 on the substrate 110 including the gate electrode 121 and the gate insulation layer 130.

The spray coating device 200 may be a spray coating device 200 used in the forming of the gate insulation layer 130.

The forming of the semiconductor layer 140 may include: preparing a second process solution by mixing a metal precursor and a stabilizer in a volatile solvent and an oxide semiconductor of the semiconductor layer 140 in a volatile solvent; spraying the second process solution on the substrate 110 through the nozzle 203 together with the carrier gas supplied through the gas supply portion 202; and evaporating the volatile solvent contained in the second process solution.

The semiconductor layer 140 may include at least one of an indium-gallium-zinc oxide (IGZO), an indium-zinc-tin oxide (IZTO), an indium-gallium-zinc-tin oxide (IGZTO), and an indium-gallium oxide (IGO), and for example, an indium (In) precursor may include indium(III) chloride (InCl₃), a gallium (Ga) precursor may include gallium(III) nitrate hydrate (Ga NO₃₃·xH₂O), a zinc (Zn) precursor may include zinc acetate dehydrate (Zn(CH₃COO)₂·2H₂O), and a tin (Sn) precursor may include tin(II) chloride dihydrate (SnCl₂·2H₂O).

The stabilizer may include ammonium acetate (CH₃CO₂NH₄)) (AA), and the solvent may include 2-methoxyethanol (CH₃OCH₂CH₂OH).

The forming of the semiconductor layer 140 may be performed under a process temperature of about 320° C. to about 380° C., more specifically, about 325° C. to about 375° C.

As described above, the forming of the semiconductor layer 140 may be performed under a process temperature of about 320° C. to about 380° C., more specifically, about 325° C. to about 375° C., and through this, the semiconductor layer 140 including the amorphous oxide semiconductor may be formed. When the process temperature for forming the semiconductor layer 140 by spray coating is higher than 380° C., the semiconductor layer 140 may include a crystallized oxide semiconductor rather than an amorphous oxide semiconductor, and when the process temperature for forming the semiconductor layer 140 by spray coating is lower than about 320° C., bubbles or the like are contained in the semiconductor layer 140 such that the film characteristic may be lowered.

The surface roughness of the semiconductor layer 140 may be low such that the average height difference of the surface roughness of the surface of the semiconductor layer 140 measured with an atomic force microscope (AFM) is about 1 nm or less, and more specifically, about 0.86 nm or less.

After the forming of the semiconductor layer 140, the source electrode 151, and the drain electrode 152 disposed on the second region 142 and the third region 143 of the semiconductor layer 140 are formed such that the thin film transistor shown in FIG. 1 can be formed.

A metal layer, for example, a single layer containing a low resistive metal such as an aluminum-based metal, a silver-based metal, or a copper-based metal, or a triple layer including a lower layer containing a refractory metal such as titanium, molybdenum, chromium, and tantalum or alloys thereof, a middle layer containing an aluminum-based metal, a silver-based metal, and a copper-based metal having low resistivity, and an upper layer containing a refractory metal such as titanium, molybdenum, chromium, and tantalum is stacked on the semiconductor layer 140, a photosensitive layer pattern is formed thereon, and the photosensitive layer pattern is etched with an etching mask such that the source electrode 151 and the drain electrode 152 may be formed.

In the thin film transistor manufacturing method according to the present embodiment, the gate insulation layer 130 and the semiconductor layer 140 are formed by a spray coating method using a spray coating device 200, and thus the forming of the gate insulation layer 130 and the forming of the semiconductor layer 140 are performed through the same spray coating process while changing and supplying the first process solution and the second process solution to one spray coating device 200 such that the manufacturing method can be simplified.

In addition, in the thin film transistor manufacturing method according to the present embodiment, the forming of the gate insulation layer 130 and the forming of the semiconductor layer 140 are performed under a process temperature of about 320° C. to about 380° C., more specifically about 325° C. to about 375° C., such that the semiconductor layer 140 may include an amorphous oxide semiconductor. As such, according to the manufacturing method of the thin film transistor according to the present embodiment, the semiconductor layer 140 may be formed to have an amorphous structure by adjusting the process temperature.

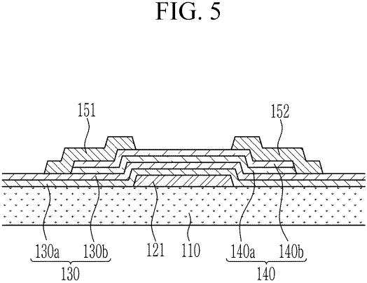

Referring to FIG. 5, a thin film transistor according to another embodiment will be described. FIG. 5 is a cross-sectional view of a thin film transistor according to another embodiment.

Referring to FIG. 5, a gate electrode 121 may be disposed on a substrate 110, and a gate insulation layer 130 may be disposed on the gate electrode 121.

The gate electrode 121 may be a single layer including any one of copper (Cu), a copper alloy, aluminum (Al), an aluminum alloy, molybdenum (Mo), and a molybdenum alloy or a plurality of layers in which metal layers are stacked.

The gate insulation layer 130 may include a first gate insulation layer 130a and a second gate insulation layer 130b disposed on the first gate insulation layer 130a.

The gate insulation layer 130 may include one of a zinc aluminum oxide (ZAO), aluminum oxide (Al₂O₃), silicon dioxide (SiO₂), and zirconium oxide (ZrO₂), and the gate insulation layer 130 may be formed by a spray coating method.

The first gate insulation layer 130a may include any one of aluminum oxide (Al₂O₃), a zinc aluminum oxide (ZAO), and zirconium oxide (ZrO₂), and the second gate insulation layer 130b may include any one of a zinc aluminum oxide (ZAO) and silicon dioxide (SiO₂). For example, the first gate insulation layer 130a and the second gate insulation layer 130b may include aluminum oxide (Al₂O₃) and a zinc aluminum oxide (ZAO), a zinc aluminum oxide (ZAO) and silicon dioxide SiO₂, and zirconium oxide (ZrO₂) and a zinc aluminum oxide (ZAO).

A semiconductor layer 140 including a first region 141, a second region 142, and a third region 143 is disposed on the gate insulation layer 130.

The semiconductor layer 140 may include an amorphous oxide semiconductor (AOS).

The semiconductor layer 140 may include a first semiconductor layer 140a and a second semiconductor layer 140b disposed on the first semiconductor layer 140a.

The first semiconductor layer 140a and the second semiconductor layer 140b each may include an amorphous oxide semiconductor.

The oxide semiconductor may include at least one of a primary metal oxide such as an indium (In) oxide, a tin (Sn) oxide, or a zinc (Zn) oxide, a binary metal oxide such as an In-Zn-based oxide, a Sn-Zn-based oxide, an Al-Zn-based oxide, a Zn-Mg-based oxide, a Sn-Mg-based oxide, an In-Mg-based oxide, or an In-Ga-based oxide, a ternary metal such as an In-Ga-Zn-based oxide, an In-Al-Zn-based oxide, an In-Sn-Zn-based oxide, a Sn-Ga-Zn-based oxide, an Al-Ga-Zn-based oxide, a Sn-Al-Zn-based oxide, an In-Hf-Zn-based oxide, an In-La-Zn-based oxide, an In-Ce-Zn-based oxide, an In-Pr-Zn-based oxide, an In-Nd-Zn-based oxide, an In-Sm-Zn-based oxide, an In-Eu-Zn-based oxide, an In-Gd-Zn-based oxide, an In-Tb-Zn-based oxide, an In-Dy-Zn-based oxide, an In-Ho-Zn-based oxide, an In-Er-Zn-based oxide, an In-Tm-Zn-based oxide, an In-Yb-Zn-based oxide, or an In-Lu-Zn-based oxide, and a quaternary metal oxide such as an In-Sn-Ga-Zn-based oxide, an In-Hf-Ga-Zn-based oxide, an In-Al-Ga-Zn-based oxide, an In-Sn-Al-Zn-based oxide, an In-Sn-Hf-Zn-based oxide, or an In-Hf-Al-Zn-based oxide.

The semiconductor layer 140 may include at least one of an indium-gallium-zinc oxide (IGZO), an indium-zinc-tin oxide (IZTO), an indium-gallium-zinc-tin oxide (IGZTO), and an indium-gallium oxide (IGO). For example, the first semiconductor layer 140a and the second semiconductor layer 140b may include at least one of an indium-gallium-zinc oxide (IGZO) and an indium-gallium oxide (IGO), and an indium-gallium-zinc-tin oxide (IGZTO) and an indium-zinc oxide (IZTO).

The semiconductor layer 140 may be formed by a spray method, and the spray solution may include a stabilizer, and the stabilizer may include ammonium acetate (CH₃CO₂NH₄) (AA).

A difference in the average height of the surface roughness of the surface of the semiconductor layer 140 measured with an atomic force microscope (AFM) may be about 1 nm or less, and more specifically, about 0.86 nm or less.

The first region 141 of the semiconductor layer 140 may be a channel region, and the second region 142 and third region 143 of the semiconductor layer 140 may be a source region and a drain region, respectively.

A source electrode 151 is disposed on the second region 142 that is the source region of the semiconductor layer 140, and a drain electrode 152 is disposed on the third region 143 that is the drain region of the semiconductor layer 140.

The source electrode 151 and the drain electrode 152 may include an aluminum-based metal, a silver-based metal, and a copper-based metal having low resistivity, and may have a triple-layered structure of a lower layer containing a refractory metal such as titanium, molybdenum, chromium, and tantalum or alloys thereof, a middle layer containing an aluminum-based metal, a silver-based metal, and a copper-based metal having low resistivity, and an upper layer containing a refractory metal such as titanium, molybdenum, chromium, and tantalum.

The gate electrode 121, the source electrode 151, and the drain electrode 152 described above form a thin film transistor together with the semiconductor layer 140, and a channel of the thin film transistor is formed between the second region 142, which is the source region of the semiconductors 141, 142, and 143, and the third region, which is the drain region.

In the thin film transistor according to the present embodiment, the gate insulation layer 130 and the semiconductor layer 140 may be formed by spray coating, and the semiconductor layer 140 may include an amorphous oxide semiconductor.

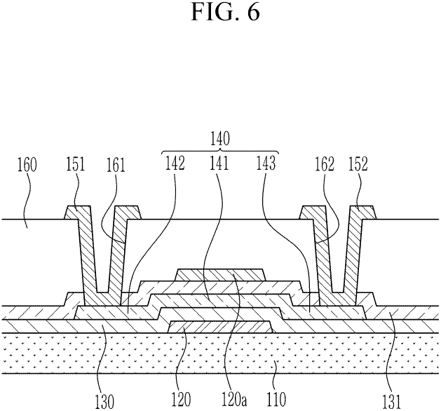

Referring to FIG. 6, a thin film transistor according to another embodiment will be described. FIG. 6 is a cross-sectional view of a thin film transistor according to another embodiment.

Referring to FIG. 6, a gate electrode 121 may be disposed on a substrate 110, and a gate insulation layer 130 may be disposed on the gate electrode 121.

The gate electrode 121 may be a single layer including any one of copper (Cu), a copper alloy, aluminum (Al), an aluminum alloy, molybdenum (Mo), and a molybdenum alloy, or a plurality of layers in which metal layers are stacked.

The gate insulation layer 130 may include one of a zinc aluminum oxide (ZAO), aluminum oxide (Al₂O₃), silicon dioxide (SiO₂), and zirconium oxide (ZrO₂), and the gate insulation layer 130 may be formed by a spray coating method.

The gate insulation layer 130 may include a first gate insulation layer and a second gate insulation layer disposed on the first gate insulation layer.

The first gate insulation layer may include any one of aluminum oxide (Al₂O₃), a zinc aluminum oxide (ZAO), and zirconium oxide (ZrO₂), and the second gate insulation layer may include any one of a zinc aluminum oxide (ZAO) and silicon dioxide (SiO₂). For example, the first gate insulation layer and the second gate insulation layer may include aluminum oxide (Al₂O₃) and a zinc aluminum oxide (ZAO), a zinc aluminum oxide (ZAO) and silicon dioxide (SiO₂), and zirconium oxide (ZrO₂) and a zinc aluminum oxide (ZAO), and the like.

A semiconductor layer 140 including a first region 141, a second region 142, and a third region 143 is disposed on the gate insulation layer 130.

The semiconductor layer 140 may include an amorphous oxide semiconductor (AOS). The oxide semiconductor may include at least one of a primary metal oxide such as an indium (In) oxide, a tin (Sn) oxide, or a zinc (Zn) oxide, a binary metal oxide such as an In-Zn-based oxide, a Sn-Zn-based oxide, an Al-Zn-based oxide, a Zn-Mg-based oxide, a Sn-Mg-based oxide, an In-Mg-based oxide, or an In-Ga-based oxide, a ternary metal such as an In-Ga-Zn-based oxide, an In-Al-Zn-based oxide, an In-Sn-Zn-based oxide, a Sn-Ga-Zn-based oxide, an Al-Ga-Zn-based oxide, a Sn-Al-Zn-based oxide, an In-Hf-Zn-based oxide, an In-La-Zn-based oxide, an In-Ce-Zn-based oxide, an In-Pr-Zn-based oxide, an In-Nd-Zn-based oxide, an In-Sm-Zn-based oxide, an In-Eu-Zn-based oxide, an In-Gd-Zn-based oxide, an In-Tb-Zn-based oxide, an In-Dy-Zn-based oxide, an In-Ho-Zn-based oxide, an In-Er-Zn-based oxide, an In-Tm-Zn-based oxide, an In-Yb-Zn-based oxide, or an In-Lu-Zn-based oxide, and a quaternary metal oxide such as an In-Sn-Ga-Zn-based oxide, an In-Hf-Ga-Zn-based oxide, an In-Al-Ga-Zn-based oxide, an In-Sn-Al-Zn-based oxide, an In-Sn-Hf-Zn-based oxide, or an In-Hf-Al-Zn-based oxide.

The semiconductor layer 140 may include at least one of an indium-gallium-zinc oxide (IGZO), an indium-zinc-tin oxide (IZTO), an indium-gallium-zinc-tin oxide (IGZTO), and an indium-gallium oxide (IGO).

The semiconductor layer 140 may be formed by a spray method, and the spray solution may include a stabilizer, and the stabilizer may include ammonium acetate (CH₃CO₂NH₄) (AA).

A difference in the average height of the surface roughness of the surface of the semiconductor layer 140 measured with an atomic force microscope (AFM) may be about 1 nm or less, and more specifically, about 0.86 nm or less.

The first region 141 of the semiconductor layer 140 may be a channel region, and the second region 142 and the third region 143 of the semiconductor layer 140 may be a source region and a drain region, respectively.

The semiconductor layer 140 may include a first semiconductor layer and a second semiconductor layer disposed on the first semiconductor layer. For example, the first semiconductor layer and the second semiconductor layer may include any one of an indium-gallium-zinc oxide (IGZO) and an indium-gallium oxide (IGO), and an indium-gallium-zinc-tin oxide (IGZTO) and an indium-zinc oxide (IZTO).

A first insulation layer 131 may be disposed on the semiconductor layer 140. The first insulation layer 131 may include one of a zinc aluminum oxide (ZAO), aluminum oxide (Al₂O₃), silicon dioxide (SiO₂), and zirconium oxide (ZrO₂), and the gate insulation layer 130 may be formed by a spray coating method.

A second gate electrode 120a may be disposed on the first insulation layer 131. The second gate electrode 120a may be a single layer including any one of copper (Cu), a copper alloy, aluminum (Al), an aluminum alloy, molybdenum (Mo), and a molybdenum alloy, or a plurality of layers in which metal layers are stacked.

The second gate electrode 120a is connected to the first gate electrode 120, and thus the same voltage may be applied to the first gate electrode 120 and the second gate electrode 120a.

A second insulation layer 160 may be disposed on the second gate electrode 120a.

The first insulation layer 131 and the second insulation layer 160 may include a first contact hole 161 and a second contact hole 162 that expose the second region 142, which is a source region of the semiconductor layer 140 and the third region 143, which is a drain region of the semiconductor layer 140.

The source electrode 151 and the drain electrode 152 may be disposed on the second insulation layer 160.

The source electrode 151 may be connected to the second region 142 which is a source region of the semiconductor layer 140 through the first contact hole 161, and the drain electrode 152 may be connected to the third region 143 which is a drain region of the semiconductor layer 140 through the second contact hole 162.

The source electrode 151 and the drain electrode 152 may include an aluminum-based metal, a silver-based metal, and a copper-based metal having low resistivity, and may have a triple-layered structure of a lower layer containing a refractory metal such as titanium, molybdenum, chromium, and tantalum or alloys thereof, a middle layer containing an aluminum-based metal, a silver-based metal, and a copper-based metal having low resistivity; and an upper layer containing a refractory metal such as titanium, molybdenum, chromium, and tantalum.

The above-described gate electrode 121, second gate electrode 120a, source electrode 151, and drain electrode 152 form a thin film transistor together with the semiconductor layer 140, and a channel of the thin film transistor is formed in the first region 141 between the second region 142, which is source regions of the semiconductors 141, 142, and 143 and the third region 143, which is drain regions of the semiconductors 141, 142, and 143.

In the thin film transistor according to the present embodiment, the gate insulation layer 130, the semiconductor layer 140, and the first insulation layer 131 may be formed by spray coating, and the semiconductor layer 140 may include an amorphous oxide semiconductor.

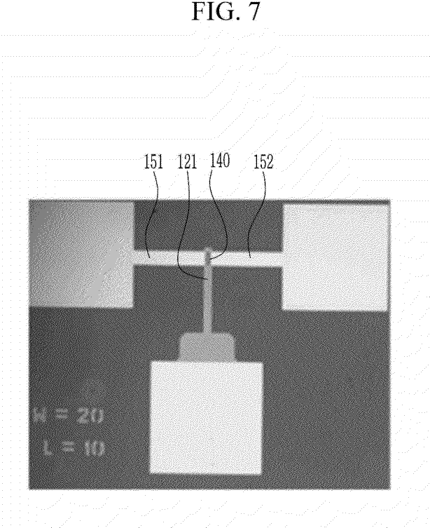

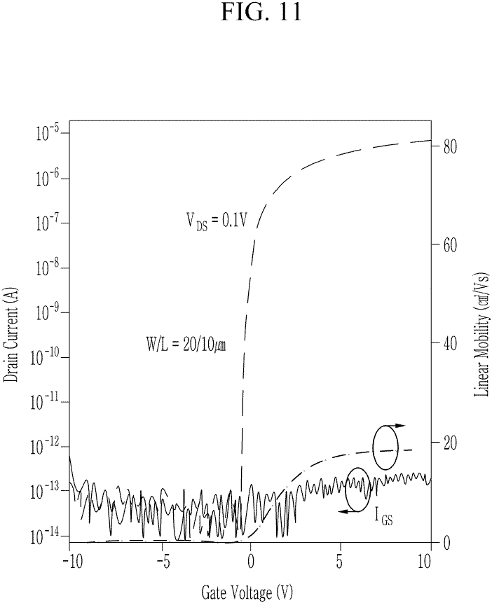

Hereinafter, an experimental example will be described with reference to FIG. 7 to FIG. 11. FIG. 7 to FIG. 10 are electron microscope photos of a result of an experimental example, and FIG. 11 is a graph illustrating a result of the experimental example.

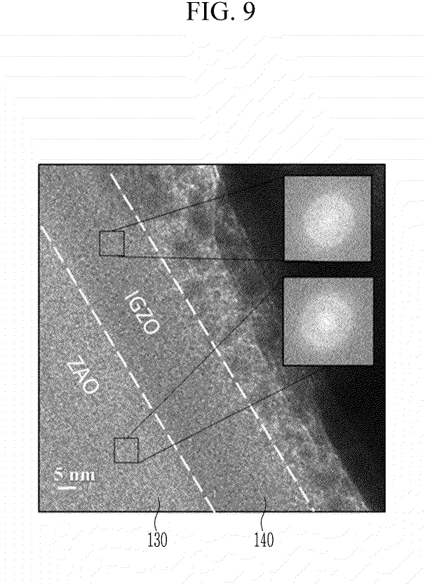

In the present experimental example, according to the thin film transistor manufacturing method according to the embodiment described with reference to FIG. 1 to FIG. 4, a thin film transistor including a gate insulation layer 130 and a semiconductor layer 140 formed by spray coating using a spray coating device 200 under a process temperature of about 375° C. was formed. An electron microscope photograph of a top surface of the thin film transistor formed in the present experimental example is shown in FIG. 5, an enlarged view of a channel portion of the semiconductor of FIG. 5 is shown in the electron microscope photo of FIG. 6, a cross-section of the gate insulation layer and the semiconductor layer of the thin film transistor and a part thereof are enlarged in the electron microscope photograph of FIG. 7, and after forming the semiconductor layer, an atomic force microscope (AFM) photograph measuring the surface roughness of the semiconductor layer is shown. In addition, a transfer curve of the thin film transistor formed in the present experimental example is shown in FIG. 9.

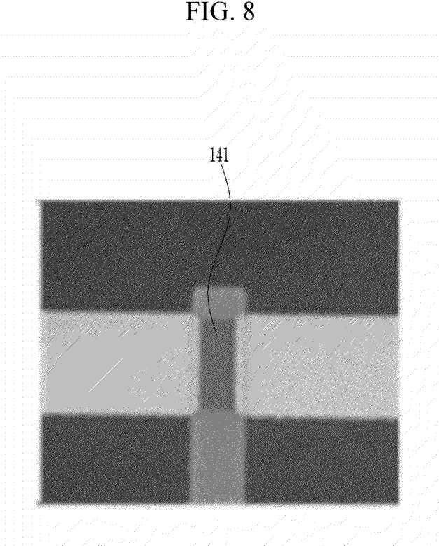

Referring to FIG. 7 and FIG. 8, as in the thin film transistor manufacturing method according to the present embodiment, it was determined that the first region 141 of the semiconductor layer 140 overlapping the gate electrode 121 and the source electrode 151 of the spray coating device 200, and the source electrode 515 and the drain electrode 152 overlapping the second region 142 and the third region 143 of the semiconductor layer 140 were well formed.

Referring to FIG. 9, according to a thin film transistor manufacturing method according to an embodiment, it was determined that a gate insulation layer and a semiconductor layer formed by a spray coating method using a spray coating device 200 were formed in an amorphous form without crystallization under a process temperature of about 375° C.

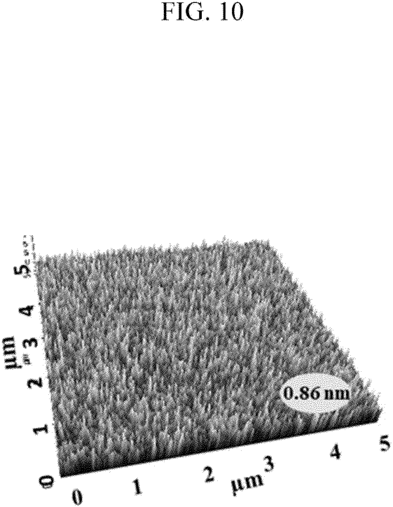

Referring to FIG. 10, according to a thin film transistor manufacturing method according to an embodiment, a difference in height of the surface of the semiconductor layer 140 formed by spray coating using the spray coating device 200 under a process temperature of about 380° C. or less, more specifically about 375° C. or less, is about 0.86 nm or less, and through this, it was determined that the surface roughness of the semiconductor layer 140 was low.

Referring to FIG. 11, it was determined that the on-off characteristic of a thin film transistor formed according to a thin film transistor manufacturing method according to an embodiment was excellent.

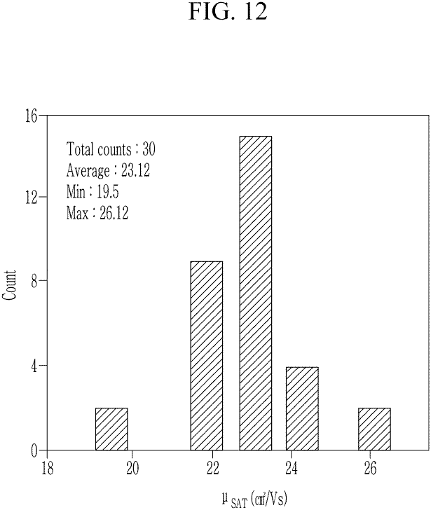

Hereinafter, referring to FIG. 12 to FIG. 14, another experimental example will be described. FIG. 12 to FIG. 14 are graphs illustrating a result of another experimental example.

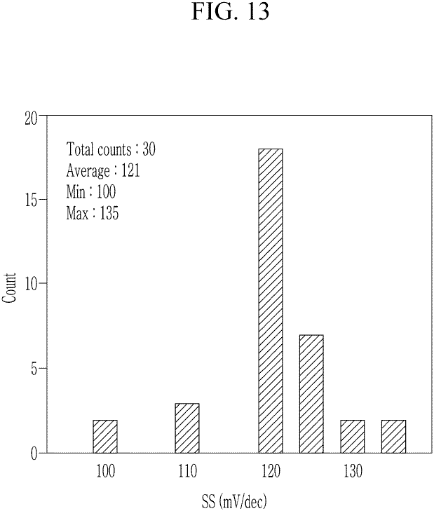

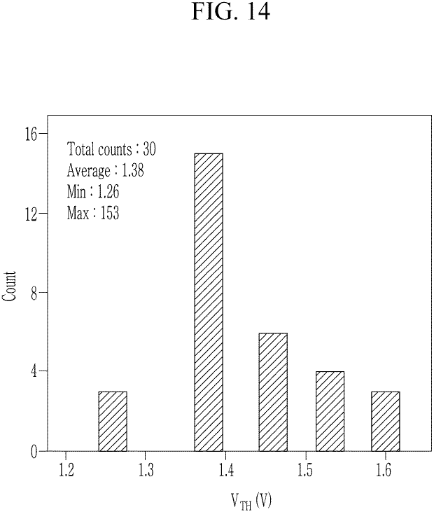

In the present experimental example, thirty thin film transistors, each including a gate insulation layer 130 and a semiconductor layer 140 formed by spray coating using a spray coating device 200 under a process temperature of about 375° C., were formed according to the thin film transistor manufacturing method described above with reference to FIG. 1 to FIG. 4, and saturation mobility, subthreshold swing (SS), and a threshold voltage (VTH) of the formed thin film transistors were measured and distribution is shown as a bar graph in FIG. 12 to FIG. 14. FIG. 12 illustrates distribution of saturation mobility of thin film transistors, FIG. 13 illustrates distribution of swings below the threshold voltage, and FIG. 14 illustrates distribution of the threshold voltage.

Referring to FIG. 12, an average value of the saturation mobility of the thin film transistors formed according to the thin film transistor manufacturing method according to the embodiment was about 23.12 cm²/Vs, a minimum value was about 19.5 cm²/Vs, and a maximum value was about 26.12 cm²/Vs.

Referring to FIG. 13, an average value of the swing below the threshold voltage of the thin film transistors formed according to the thin film transistor manufacturing method according to the embodiment was 121 mV/dec, a minimum value was about 100 V/dec, and a maximum value was about 135 V/dec.

Referring to FIG. 14, an average value of the threshold voltage of the thin film transistors formed according to the thin film transistor manufacturing method according to the embodiment was about 1.38 V, a minimum value was about 1.26 V, and a maximum value was about 1.53 V.

As such, it was determined that the performance characteristic of the thin film transistors formed according to the thin film transistor manufacturing method according to the embodiment was excellent and the deviation was not large.

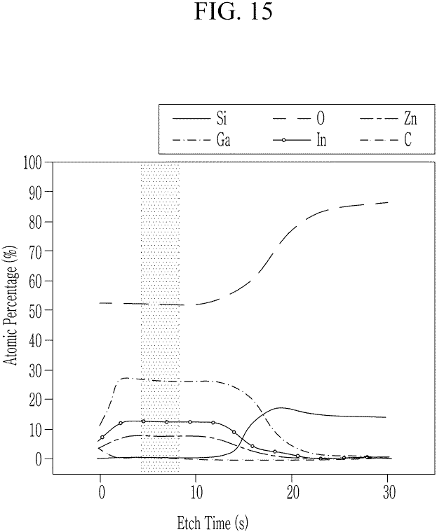

Next, referring to FIG. 15, another experimental example will be described. FIG. 15 is a graph showing results of another experimental example.

In the present experimental example, like the forming of the semiconductor layer 140 according to the thin film transistor manufacturing method according to the embodiment, a semiconductor layer 140 made of an amorphous indium-gallium-zinc oxide (IGZO) was formed by using a spray coating method using a spray coating device 200 on a glass substrate under a process temperature of about 375° C., and an atomic profile was measured through a single particle analysis (SPA) and a result is shown in FIG. 13.

Referring to FIG. 15, it was determined that the atoms of indium (In), gallium (Ga), zinc (Zn), and oxygen (O) forming the semiconductor layer 140 were well formed uniformly along the thickness direction of the semiconductor layer 140.

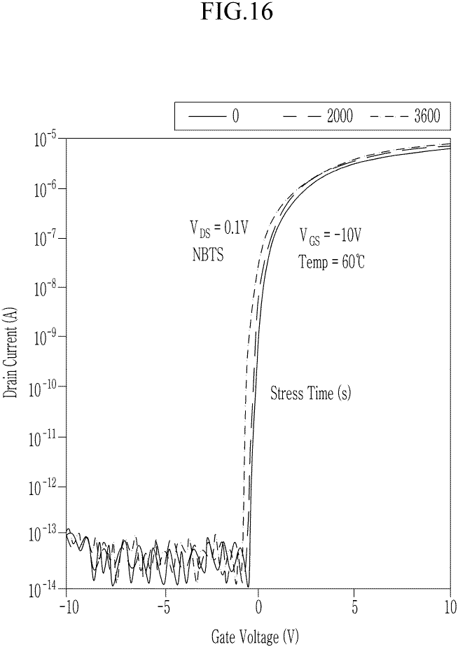

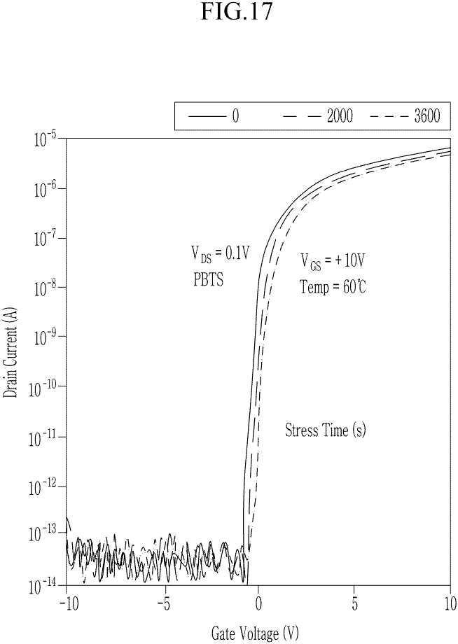

Next, referring to FIG. 16 and FIG. 17, another experimental example will be described. FIG. 16 and FIG. 17 are graphs illustrating results of another experimental example.

In the present experimental example, a thin film transistor including a gate insulation layer 130 and a semiconductor layer 140 made of an amorphous indium-gallium-zinc oxide (IGZO) formed by spray coating using a spray coating device 200 under a process temperature of about 375° C. were formed according to the thin film transistor manufacturing method described above with reference to FIG. 1 to FIG. 4, a stress was applied to the thin film transistor, and a transfer curve of the thin film transistor was measured for the cases where the time for applying the stress is 0 s, 2000 s, and 3600 s, and the results are shown in FIG. 16 and FIG. 17. FIG. 16 illustrates a result of a negative bias temperature stress (NBTS), and FIG. 17 illustrates a result of a positive bias temperature stress (PBTS).

Referring to FIG. 16 and FIG. 17, it was determined that the performance of the thin film transistor formed according to the thin film transistor manufacturing method according to the embodiment does not change significantly even when stress is applied. Through this, it was confirmed that the thin film transistor formed according to the thin film transistor manufacturing method according to the embodiment had high stability.

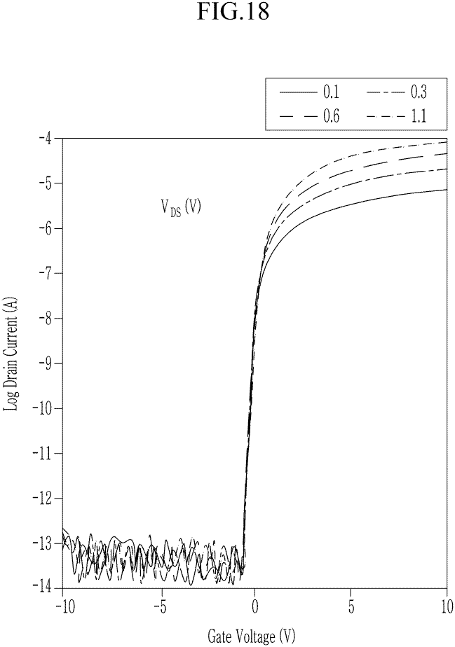

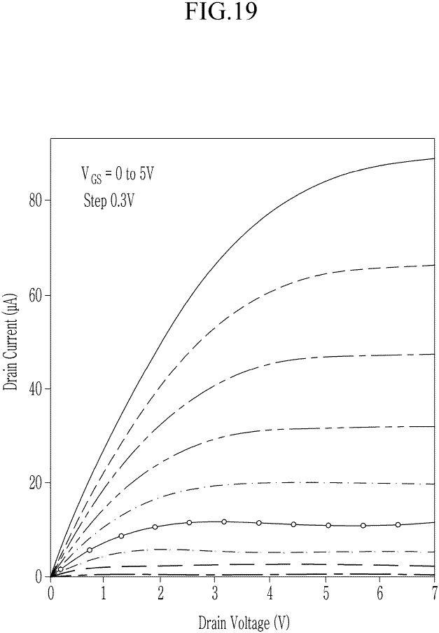

Referring to FIG. 18 and FIG. 19, another experimental example will be described. FIG. 18 and FIG. 19 are graphs illustrating results of another experimental example.

In the present experimental example, a thin film transistor including a gate insulation layer 130 and a semiconductor layer 140 of an amorphous indium-gallium-zinc oxide (IGZO) formed by spray coating using a spray coating device 200 under a process temperature of about 375° C. were formed according to the thin film transistor manufacturing method described above with reference to FIG. 1 to FIG. 4, and a transfer curve was measured while changing a source drain voltage V_{DS} to 0.1 V, 0.3 V, 0.6 V, and 1.1 V, and the result is shown in FIG. 16, and a current was measured while changing a gate voltage V_{GS} from about 0 V to about 5 V, and the result is shown in FIG. 19.

Referring to FIG. 18, it was determined that the on-off characteristic of the thin film transistor formed according to the thin film transistor manufacturing method according to the embodiment was well maintained even when the source drain voltage V_{DS} was changed.

Referring to FIG. 19, it was determined that the drain current value of the thin film transistor formed according to the thin film transistor manufacturing method according to the embodiment was saturated to a constant value according to the gate voltage V_{GS}. Through this, it was confirmed that the thin film transistor formed according to the thin film transistor manufacturing method according to the embodiment had stable performance because the amount of current change according to the gate voltage V_{GS} was not large.

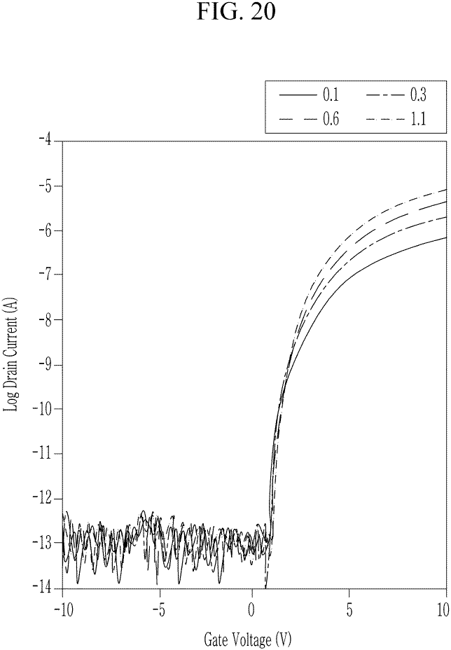

Next, another experimental example will be described with reference to FIG. 20 to FIG. 28. FIG. 20 to FIG. 28 are graphs illustrating results of another experimental example.

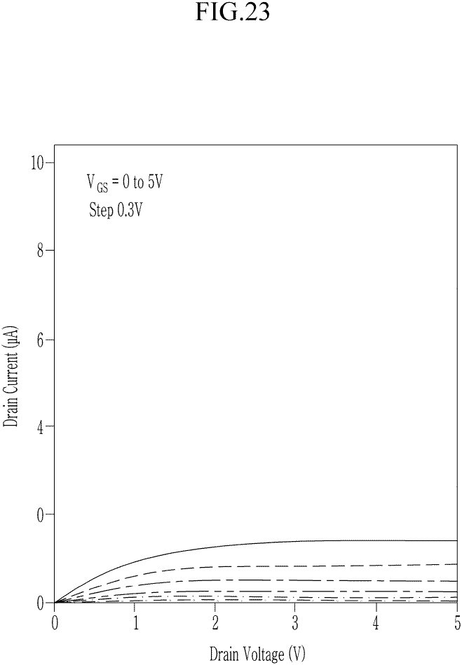

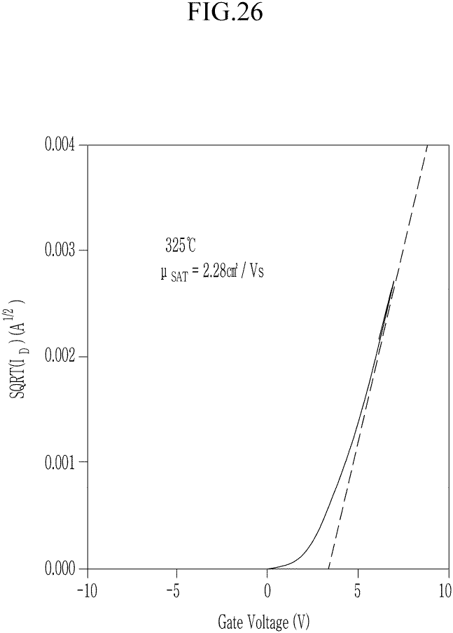

In the present experimental example, according to the thin film transistor manufacturing method described above with reference to FIG. 1 to FIG. 4, a thin film transistor including a gate insulation layer 130 and a semiconductor layer 140 of an amorphous indium-gallium-zinc oxide (IGZO) is formed by spray coating using a spray coating device 200 under a process temperature of about 325° C. in a first case, a thin film transistor including a gate insulation layer 130 and a semiconductor layer 140 of an amorphous indium-gallium-zinc oxide (IGZO) is formed by spray coating using a spray coating device 200 under a process temperature of about 350° C. in a second case, and a thin film transistor including a gate insulation layer 130 and a semiconductor layer 140 of an amorphous indium-gallium-zinc oxide (IGZO) is formed by spray coating using a spray coating device 200 under a process temperature of about 375° C. in a third case. Then, a transfer curve was measured while changing a source drain voltage V_{DS} to about 0.1 V, about 0.3 V, about 0.6 V, and about 1.1 V, with respect to the first case, the second case, and the third case, and results are shown in FIG. 20 to FIG. 22, a current was measured while changing a gate voltage V_{GS} from about 0 V to about 5 V, and results are shown in FIG. 23 to FIG. 25, and saturation mobility (µsat) was measured and results are shown in FIG. 26 to FIG. 28.

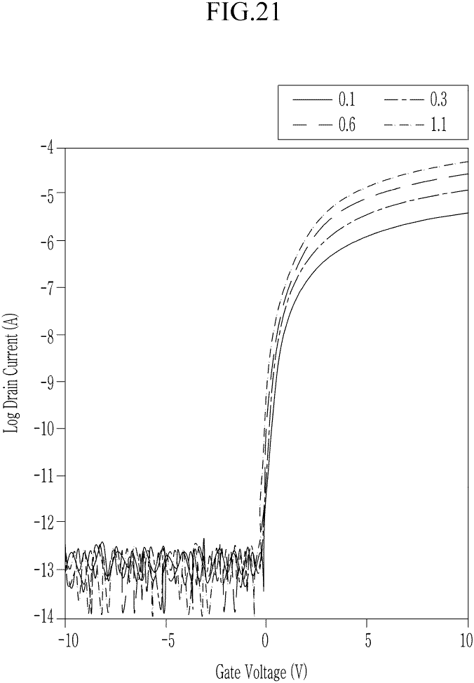

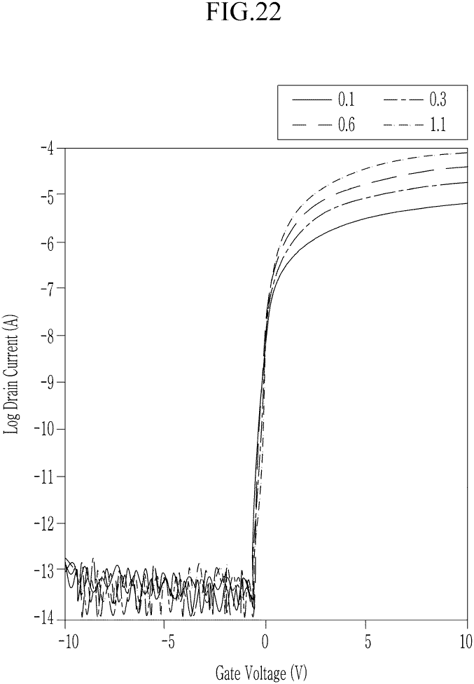

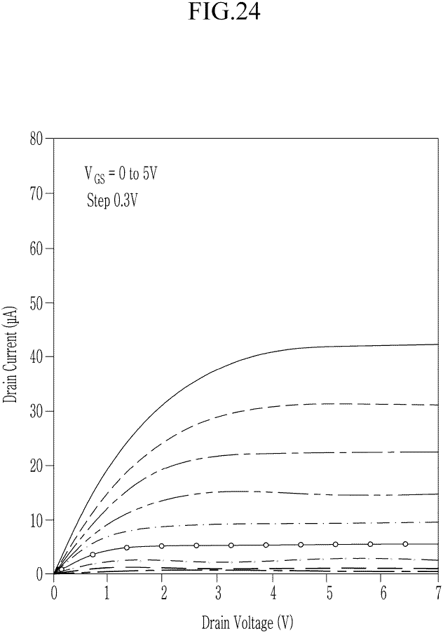

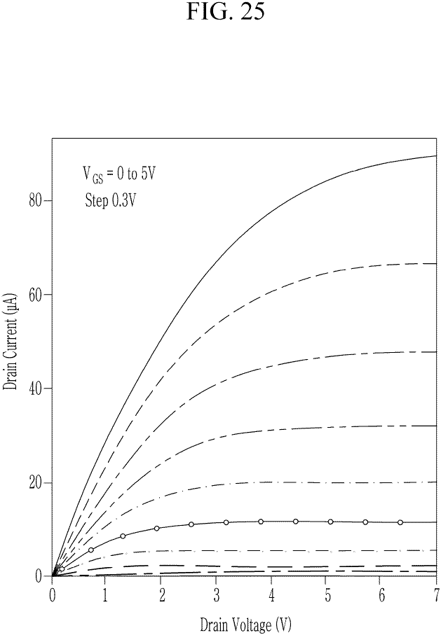

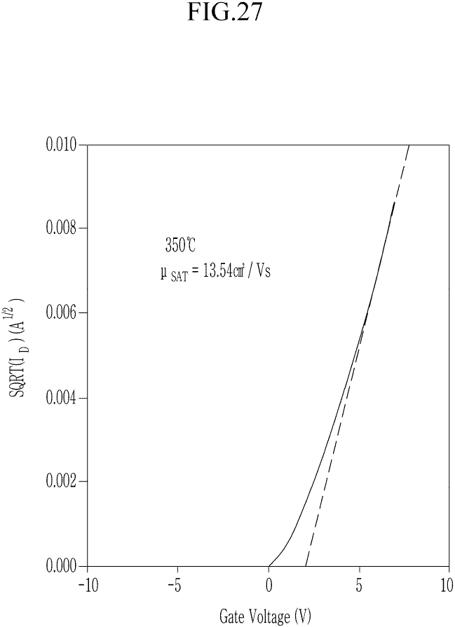

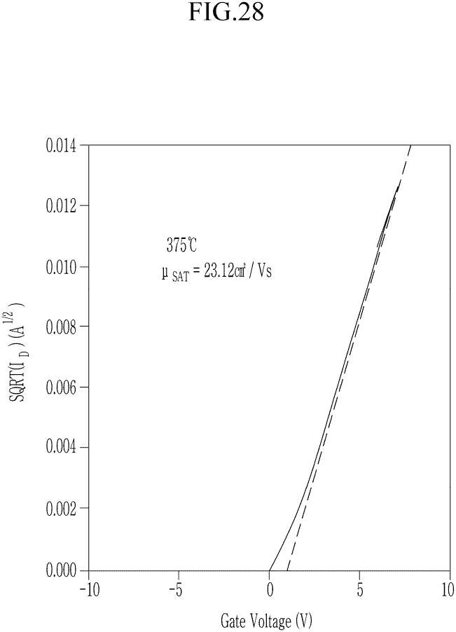

FIG. 20, FIG. 23, and FIG. 26 illustrate results of the first case, FIG. 21, FIG. 24, and FIG. 27 illustrate results of the second case, and FIG. 22, FIG. 25, and FIG. 28 illustrate results of the third case.

Referring to FIG. 20 to FIG. 22, as in the thin film transistor manufacturing method according to the embodiment, it was determined that the on-off characteristic of the thin film transistor including the semiconductor layer formed by using the spray coating method under the process temperature of about 320° C. to about 380° C., more specifically, about 325° C. to about 375° C., was well maintained even when the source drain voltage V_{DS} was changed.

Referring to FIG. 23 to FIG. 25, as in the thin film transistor manufacturing method according to the embodiment, the thin film transistor including the semiconductor layer formed by using the spray coating method under the process temperature of about 320° C. to about 380° C., more specifically, about 325° C. to about 375° C., was saturated to a constant value according to the gate voltage V_{GS}. In addition, it was determined that a drain current value increased as the process temperature for forming the semiconductor layer 140 including the amorphous oxide semiconductor by spray coating using the spray coating device 200 increased.

Referring to FIG. 26 to FIG. 28, as in the thin film transistor manufacturing method according to the embodiment, it was determined that the thin film transistors including the semiconductor layer formed by spray coating under a process temperature of about 320° C. to about 380° C., more specifically about 325° C. to about 375° C., have a saturation mobility of about 2.28 cm²/Vs, about 13.54 cm²/Vs, and about 23.12 cm²/Vs, and the saturation mobility value increased as the process temperature for forming the semiconductor layer 140 including the amorphous oxide semiconductor formed by spray coating using the spray coating device 200 increased.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### Description of Symbols

110: substrate,
120: gate electrode
130: gate insulation layer
140: semiconductor layer
151: source electrode
152: drain electrode
200: spray coating device
201: solution supply portion
202: gas supply portion
203: nozzle

What is claimed is:

1. A thin film transistor comprising:
a gate electrode disposed on a substrate;
a semiconductor layer that overlaps the gate electrode, while disposing the gate insulation layer therebetween; and
a source electrode and a drain electrode that contact the semiconductor layer,
wherein the semiconductor layer comprises an amorphous oxide semiconductor,
the amorphous oxide semiconductor is formed by spray coating, and an average surface roughness difference of an atomic force microscope (AFM) of the amorphous oxide semiconductor is about 1 nm and less.

2. The thin film transistor of claim 1, wherein
the gate insulation layer contains a zinc aluminum oxide (ZAO).

3. The thin film transistor of claim 2, wherein
the semiconductor layer contains indium.

4. The thin film transistor of claim 3, wherein
the semiconductor layer contains at least one of an indium-gallium-zinc oxide (IGZO), an indium-zinc-tin oxide (IZTO), an indium-gallium-zinc-tin oxide (IGZTO), and an indium-gallium oxide (lGO).

5. The thin film transistor of claim 4, further comprising a first gate electrode that overlaps the semiconductor layer,
wherein the first gate electrode is applied with the same voltage applied to the gate electrode.

6. The thin film transistor of claim 4, wherein
the gate insulation layer comprises a first gate insulation layer and a second gate insulation layer disposed on the first gate insulation layer.

7. The thin film transistor of claim 6, wherein
the first gate insulation layer contains any one of aluminum oxide (Al₂O₃), a zinc aluminum oxide (ZAO), and a zirconium oxide (ZrO₂), and the second gate insulation layer contains any one of a zinc aluminum oxide (ZAO) and silicon dioxide (SiO₂).

8. The thin film transistor of claim 1, wherein
the semiconductor layer comprises a first semiconductor layer and a second semiconductor layer disposed on the first semiconductor layer.

9. The thin film transistor of claim 8, wherein
the first semiconductor layer comprises any one of an indium-gallium-zinc oxide (IGZO) and an indium-gallium-zinc-tin oxide (IGZTO), and
the second semiconductor layer comprises any one of an indium-gallium oxide (IGO) and an indium-zinc oxide (IZTO).

10. A thin film transistor manufacturing method comprising:
forming a gate electrode on a substrate;
forming a gate insulation layer on the gate electrode;
forming a semiconductor layer on the gate insulation layer; and
forming a source electrode and a drain electrode that contact the semiconductor layer,
wherein the forming of the gate insulation layer and the forming of the semiconductor layer comprise spray coating on the substrate.

11. The thin film transistor manufacturing method of claim 10, wherein
the forming of the gate insulation layer comprises:
preparing a first process solution in a spray coating device;
spraying the first process solution to the substrate together with a carrier gas; and
evaporating a volatile solvent contained in the first process solution.

12. The thin film transistor manufacturing method of claim 11, wherein
the forming of the semiconductor layer comprises:
preparing a second process solution in the spray coating device;
spraying the second process solution to the substrate together with the carrier gas; and
evaporating a volatile solvent contained in the second process solution.

13. The thin film transistor manufacturing method of claim 12, wherein
the forming of the semiconductor layer is carried out under a process temperature of about 320° C. to about 380° C.

14. The thin film transistor manufacturing method of claim 13, wherein
the forming of the semiconductor layer is carried out under a process temperature of about 325° C. to about 375° C.

15. The thin film transistor manufacturing method of claim 14, wherein
the gate insulation layer contains a zinc aluminum oxide (ZAO), and
the first process solution contains a precursor of the zinc aluminum oxide.

16. The thin film transistor manufacturing method of claim 14, wherein
the semiconductor layer further comprises an amorphous oxide semiconductor, and
the second process solution comprises a precursor of the oxide semiconductor.

17. The thin film transistor manufacturing method of claim 16, wherein
the semiconductor layer contains indium.

18. The thin film transistor manufacturing method of claim 17, wherein
the semiconductor layer comprises at least one of an indium-gallium-zinc oxide (IGZO), an indium-zinc-tin oxide (IZTO), an indium-gallium-zinc-tin oxide (IGZTO), and an indium-gallium oxide (IGO).

19. The thin film transistor manufacturing method of claim 12, wherein:
the forming of the gate insulation layer is carried out under a process temperature of about 320° C. to about 380° C.

20. The thin film transistor manufacturing method of claim 19, wherein:
the forming of the gate insulation layer is carried out under a process temperature of about 325° C. to about 375° C.
